(19) United States
(12) Patent Application Publication
(10) Pub. No.: US 2021/0305031 A1
(43) Pub. Date: Sep. 30, 2021

(54) METHOD FOR MANUFACTURING THIN FILM RESISTIVE LAYER

(71) Applicant: VIKING TECH CORPORATION, Hukou Township (TW)

(72) Inventors: CHENG-CHUNG CHIU, Hukou Township (TW); CHI-YU LU, Hukou Township (TW)

(21) Appl. No.: 16/929,796

(22) Filed: Jul. 15, 2020

(30) Foreign Application Priority Data
Mar. 25, 2020 (TW) 109109966

(51) Int. Cl. H01J 37/34; C23C 14/35

(52) U.S. Cl. CPC H01J 37/3405; C23C 14/35

(57) ABSTRACT

The present invention discloses a method for preparing a thin film resistive layer. A tantalum nitride layer is formed on the surface of a substrate by a magnetron sputtering method, then a tantalum pentoxide layer is formed on the tantalum nitride layer by same method. Finally, both the tantalum nitride layer and the tantalum pentoxide layer are treated with an annealing process to obtain the thin film resistive layer with a low resistance change rate.

### BACKGROUND OF THE INVENTION

### 1. Field of the Invention

The present invention relates to a method for manufacturing a thin film resistive layer, and particularly to the method for manufacturing the thin film resistive layer with stable resistance value.

### 2. Description of the Prior Art

A general reactive DC sputtering method is to react a reactive gas with sputtered particles on a surface of a substrate. The coating composition is related to the partial pressure of the reactive gas. The low partial pressure causes insufficient reactants, otherwise, the reactive gas cannot fully react with the sputtered particles, causing residual gas reacts with the surface of the target material to form compounds, and the compound-coated target material will reduce the sputtering yield that is called target poisoning.

In addition, with the advancement of the technology level of the electronics industry and the demand for long-term operation of electronic equipment, there are further requirements for the stability of the resistance value of the resistor element.

### SUMMARY OF THE INVENTION

In order to improve above problem, the present invention provides a method for manufacturing a thin film resistive layer, using a magnetron sputtering method to form a tantalum nitride layer on the surface of the substrate, and then form a tantalum pentoxide layer on the tantalum nitride layer to obtain a thin film resistive layer with stable resistance value. The thin film resistive layer formed by this method has the advantages of good adhesion, high density, uniform film thickness, and fast deposition speed, and can solve the target poisoning phenomenon caused by the general reactive DC sputtering method.

Below, embodiments accompanied with the attached drawings are employed to explain the objectives, technical contents, characteristics and accomplishments of the present invention.

### BRIEF DESCRIPTION OF THE DRAWINGS

FIG. 1 is a flowchart of a method of manufacturing a thin film resistive layer according to the present invention.

FIG. 2 is a cross-sectional view of a thin film resistive layer according to the present invention.

### DESCRIPTION OF THE PREFERRED EMBODIMENTS

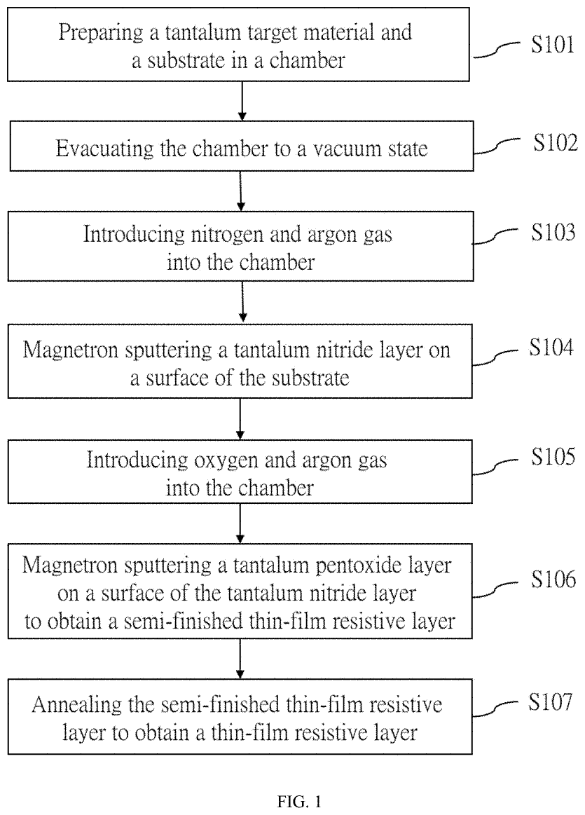

Refer to FIG. 1, which is flowchart of a method of manufacturing a thin film resistive layer according to the present invention. First, preparing a tantalum (Ta) target material and a substrate in a chamber, as shown in step S101, wherein the purity of the tantalum target is greater than 99.99 wt %. Evacuating the chamber to a vacuum state, as shown in step S102. Introducing nitrogen gas into the chamber, as shown in step S103. Impulse DC magnetron sputtering a tantalum nitride (TaN) layer on a surface of the substrate, as shown in step S104. Introducing oxygen gas into the chamber, as shown in step S105. Impulse DC magnetron sputtering a tantalum pentoxide (Ta2O5) layer on a surface of the tantalum nitride layer to obtain a semi-finished thin-film resistive layer, as shown in step S106. Finally, annealing the semi-finished thin-film resistive layer in 150-750° C. environment for 5 minutes to 24 hours to obtain a thin-film resistive layer, which the temperature coefficient of resistance (TCR) is 0±3 ppm/° C., as shown in step S107. In some embodiments, the step of forming the tantalum nitride layer by magnetron sputtering with nitrogen gas and forming the tantalum pentoxide layer by magnetron sputtering with oxygen gas can be performed in different and independent chambers or different and connected chambers.

In the step of introducing nitrogen and oxygen gas into the chamber, non-reactive gas can be simultaneously introduced into the chamber, such as argon gas or its homologous elements. In this embodiment, the ratio of nitrogen gas to argon gas is 1:4-1:999, and the ratio of oxygen gas to argon gas is 1:1.5-1:999.

In the step of impulse DC magnetron sputtering, the sputtering temperature of the tantalum nitride layer and the tantalum pentoxide layer is 100-450° C., the sputtering power is 0.25-2.5 kilowatts (kW) and the sputtering time is 5-50 minutes, wherein the sputtering temperature is preferably 200±2° C.

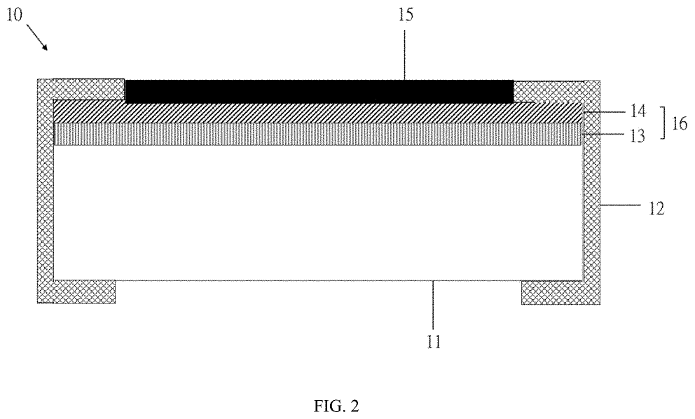

Refer to FIG. 2, which is cross-sectional view of a thin film resistive layer according to the present invention. In this embodiment, the thin film resistor 10 comprises a substrate 11, a tantalum nitride layer 13, a tantalum pentoxide layer 14 and two electrodes 12, wherein the tantalum nitride layer 13 and the tantalum pentoxide layer 14 serve as resistive layers 16, and the tantalum oxide layer 13 and the tantalum pentoxide layer 14 are obtained by the above manufacturing process.

The tantalum nitride layer 13 substantially covers an upper surface of the substrate 11, and the tantalum pentoxide layer 14 substantially covers on the tantalum nitride layer 13, wherein the thickness of the tantalum pentoxide layer 14 is 10-200 nm.

The two electrodes 12 are separately disposed at both ends of the substrate 11, and are electrically connected to the tantalum nitride layer 13 and the tantalum pentoxide layer 14, respectively, wherein the two electrodes 12 can overlap, non-overlap, or partially overlap the tantalum nitride Layer 13 and tantalum pentoxide layer 14. In some embodiments, the two electrodes 12 can respectively extend along the side of the substrate 11 to a lower surface of the substrate 11, so the front electrode on the upper surface of the substrate 11 and the back electrode on the lower surface of the substrate 11 are connected to each other.

The substrate 11 used in the present invention can be a precision ceramic substrate such as aluminum oxide, aluminum nitride, or other oxide metal materials or other types of substrates with good heat dissipation property. The substrate 11 is generally arranged in a rectangular shape, or in other suitable shapes.

In the above embodiment, further comprises a protective layer 15 covered on the tantalum pentoxide layer 14, and the two electrodes 12 are exposed from the protective layer 15.

In the aging test, the resistance change rate of the thin-film resistive layer of the present invention is less than 0.05% after being placed in an environment of two standard atmospheric pressures (atm), 85% relative humidity (RH) and 130° C. for 96 hours. Compared with the resistance change rate of the general thin film resistive layer is greater than 10% or short circuit, the thin film resistive layer of the present invention has more stable resistance value performance.

In summary, the thin-film resistive layer of the present invention provides a magnetron sputtering method to sequentially form a tantalum nitride layer and a tantalum pentoxide layer on the surface of the substrate. The thin-film resistive layer of the present invention has the advantages of good adhesion, high density, uniform thickness, fast deposition speed and low temperature coefficient of resistance.

The embodiments described above are merely illustrative of the technical spirit and features of the present invention, and are intended to enable those skilled in the art to understand the present invention and practice the present invention. The scope of the patent, that is, the equivalent changes or modifications made by the spirit of the present invention, should still be included in the scope of the patent of the present invention.

What is claimed is:

1. A method for manufacturing a thin film resistive layer, comprising:
magnetron sputtering a tantalum nitride layer on a surface of a substrate in a chamber, wherein the sputtering temperature is 100-450° C., the sputtering power is 0.25-2.5 kW and the sputtering time is 5-50 minutes;
magnetron sputtering a tantalum pentoxide layer on a surface of the tantalum nitride layer to obtain a semi-finished thin film resistive layer, wherein the sputtering temperature was 100-450° C., the sputtering power was 0.25-2.5 kW and the sputtering time was 5-50 minutes; and
annealing the semi-finished thin-film resistive layer to obtain a thin-film resistive layer.

2. The method according to claim 1, wherein further comprises introducing nitrogen gas and non-reactive gas to the chamber before the step of magnetron sputtering the tantalum nitride layer on the surface of the substrate, and introducing oxygen gas and the non-reactive gas to the chamber before the step of magnetron sputtering the tantalum pentoxide layer on the surface of the tantalum nitride layer.

3. The method according to claim 2, wherein the ratio of nitrogen to the non-reactive gas is 1:4-1:999, and the ratio of oxygen to the non-reactive gas is 1:1.5-1:999.

4. The method according to claim 1, wherein the annealing temperature is 150-750° C. and the annealing time is 5 minutes to 24 hours in the annealing step.

5. The method according to claim 1, wherein the resistance temperature coefficient of the thin-film resistive layer is 0±3 ppm/° C.
